(19) United States
(12) Patent Application Publication
(10) Pub. No.: US 2006/0133548 A1
(43) Pub. Date: Jun. 22, 2006

(54) Apparatus and method to calibrate amplitude and phase imbalance for communication receivers

(76) Inventors: Joungheon Oh, Ladera Ranch, CA (US); Yuh-Chun Lin, Irvine, CA (US); Chia-En Wu, San Gabriel, CA (US)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(21) Appl. No.: 11/013,360

(22) Filed: Dec. 17, 2004

(51) Int. Cl. H03D 1/04

(52) U.S. Cl. 375/346

(57) ABSTRACT

The present invention provides apparatus and method for calibrating I/Q imbalance in a direct conversion transmitter-receiver, including generating a complex sinusoidal signal with a center frequency at ωᵢ, sending the sinusoidal signal to the receiver and using FFT to estimate the I/Q the phase φ, the gain imbalance ε, and phase imbalance θ. The input signal is calibrated according to the estimated I/Q amplitude and phase imbalance.

### BACKGROUND

1. Field of the Invention

The present invention relates generally to wireless local area network (WLAN) devices. More particularly, the present invention provides a method and device for amplitude and phase imbalance calibration in a direct conversion wireless receiver.

2. Background

A conventional radio receiver down-converts a radio frequency (RF) signal to an intermediate frequency (IF) signal, and subsequently down-converts the IF signal to a baseband (BB) signal. Such a receiver structure is called a super-heterodyne receiver. One advantage of a super-heterodyne receiver is that better image rejection can be achieved in the IF stage. One drawback of such receiver is that an additional IF surface-acoustic-wave (SAW) filter is usually required.

A relatively new receiver structure is called a direct conversion. A direct conversion receiver directly down-converts the RF signal to a BB signal, thereby eliminating the IF stage. By eliminating the IF stage, a direct conversion receiver eliminates the need for IF components, especially the SAW filter. As a result, the cost of the receiver is reduced. However, additional issues require consideration. One such issue is the in-phase/quadrature (“I/Q”) imbalance introduced by quadrature mixing. The issue of quadrature mixing is also present with a super-heterodyne receiver. However, because the quadrature mixing in the super-heterodyne receiver is performed at IF, the I/Q balance can be readily maintained. A direct conversion receiver, on the other hand, performs quadrature mixing at RF, making I/Q balance much more difficult to maintain.

In quadrature mixing, a quadrature mixer shifts a local oscillator output by 90 degrees. Any amplitude or phase imbalance between the in-phase (I) and quadrature (Q) signal paths can cause an imperfect receiving constellation. The resultant constellation errors will, in turn, increase the demodulation error probability of the baseband processor. For example, in the OFDM (Orthogonal Frequency Division Multiplexing) modulation scheme with 64-QAM (Quadrature Amplitude Modulation), used in many wireless communication systems including IEEE 802.11a and 802.11g WLAN, the received signal must have minimum distortion due to I/Q amplitude and phase imbalance.

I/Q amplitude and phase imbalance is also known as I/Q mismatch. I/Q mismatch in a receiver can be compensated or calibrated by different methods. One conventional scheme for such compensation or calibration is described in Lovelace, D. et al., “Self Calibration Quadrature Generator with Wide Frequency Range”, IEEE Radio Frequency Integrated Circuits (RFIC) Symposium pp: 147-151, 8-11 Jun. 1997 (“Lovelace”). In Lovelace, analog circuits are implemented in the RF receiver part to compensate for the I/Q errors. The analog circuitry locally resides in the RF transceiver IC and neither the base-band processor nor the software modifications are required to execute the I/Q imbalance calibration. However, the analog circuitry requires extra hardware and costs more.

Another conventional technique is the passive I/Q mismatch calibration systems is described in US Patent Application No. US2003/0206603 A1 to Husted (“Husted”). In Husted, the received signals are processed in the baseband processor to obtain statistical characteristics when the communication system is normally in the receiver mode. Based on the statistical information, I/Q imbalance calibration factors can be generated and used to compensate for errors. Although the system disclosed in Husted requires no extra hardware in the analog portions, both the real time circuits to calculate the statistical information and the compensation circuits both have to be added in the baseband processor. As a result, there is extra hardware and extra power consumption in the baseband processor. Moreover, the received signals, having varying signal strengths, can cause the statistical information to fluctuate, thereby reducing the accuracy of the system disclosed in Husted. Further, collection of the statistical information takes a relatively long time. Another drawback is that passive I/Q mismatch calibration schemes such as described in Husted are difficult to implement in the production-line test.

An alternative active receiver I/Q imbalance compensation method is described in Roger A. Green, “An Optimized Multi-Tone Calibration Signal for Quadrature Receiver Communication Systems”, 10th IEEE workshop on Statistical Signal and Array Processing, pp. 664-667, 2000 (“Green”). In Green, an optimized multi-tone signal is generated for use in a real-time Linear Regression (LR) calibration scheme to correct amplitude and phase imbalance in an I/Q receiver. Adaptive filters can be used to track the changes and provide updates.

Achieving high throughput performance for wireless standards, e.g. 802.11a or 802.11g WLAN, represents new challenges ranging from system engineering to circuit design. Even process variations resulting manufacturing can cause poor yield rate, which can cause unacceptable I/Q mismatch.

It is apparent that an improved method and device for amplitude and phase imbalance calibration is needed in a direct conversion WLAN receiver. As discussed below, the present invention provides a method and device for a direct conversion wireless receiver with improved amplitude and phase Imbalance calibration capability. With this design, the specification in amplitude and phase imbalance for a RF receiver can be relaxed and hence improve the yield of the transceiver IC.

### BRIEF SUMMARY OF THE INVENTION

According to the present invention, techniques directed to WLAN devices are provided. More particularly, the invention provides a method and device for amplitude and phase imbalance calibration in a wireless receiver with a structure. Merely by way of example, the invention has been applied to a direct conversion receiver incorporating I/Q imbalance calibration. But it would be recognized, however, that the invention has a much broader range of applicability. For example, the invention can be applied to other receivers which require I/Q imbalance calibration.

In a specific embodiment, the present invention provides a direct conversion transmitter-receiver with I/Q imbalance calibration, including an input signal, a transmitter, a receiver, and also includes means for generating a complex sinusoidal signal, means for estimating the I/Q imbalance, and means for calibrating the I/Q imbalance in the input signal. The invention can also include a local oscillator and a 90-degree phase shifter. The I/Q imbalance can be caused by the local oscillator and by the 90-degree phase shifter.

In another specific embodiment, the present invention provides a switch to choose between a calibration mode and a normal receiving/transmitting mode; in the calibration mode the complex sinusoidal signal is used to estimate the I/Q imbalance, and in the normal receiving/transmitting mode the estimated I/Q imbalance is used to calibrate the input signal.

In other embodiments, the present invention provides for device and method for estimating the phase φ, the gain imbalance ε, and the phase imbalance θ using the complex sinusoidal signal generated in the transmitter/receiver and for calibrating the input signal using the estimated gain imbalance ε and phase imbalance θ.

Numerous benefits may be achieved using the present invention over conventional techniques. For example, the present invention provides an efficient method and device for estimating the amplitude and phase imbalance in the I and Q paths of a direct-conversion receiver which already implements IFFT/FFT (Inverse Fast Fourier Transform and Fast Fourier Transform) circuitry in the baseband modem. IEEE 802.11a or 802.11g WLAN standards use OFDM (Orthogonal Frequency Division Multiplexing) modulations for wireless transmission. An OFDM receiver employs FFT circuitry to demodulate the received signal in its normal receiving mode. According to embodiments of the present invention, that same FFT circuitry can be used for I/Q mismatch estimation. As a result, such an embodiment of the present invention provides the I/Q imbalance calibration function with minimal additional circuitry for an 802.11a or 802.11g WLAN receiver or, for that matter, any receiver which has IFFT/FFT circuitry for transmission/receiving. One or more of these benefits may be achieved by embodiments of the present invention. These and other benefits are described throughout the present specification and more particularly below. Various additional objects, features, and advantages of the present invention can be more fully appreciated with reference to the detailed description and accompanying drawings that follow. Other variations, modifications, and alternatives to the embodiments of the present invention described herein would be apparent to those skilled in the art in light of the detailed description and accompanying drawings.

### BRIEF DESCRIPTION OF DRAWINGS

FIG. 1 is a simplified drawing illustrating a WLAN direct conversion transceiver according to an embodiment of the present invention;

FIG. 2A is a simplified block diagram illustrating an I/Q imbalance calibration matrix according to an embodiment of the present invention;

FIG. 2B is a simplified block diagram illustrating an I/Q imbalance calibration matrix according to an alternative embodiment of the present invention.

### DETAILED DESCRIPTION OF THE INVENTION

The present invention relates generally to WLAN devices. More particularly, the invention provides a method and device for amplitude and phase Imbalance calibration in a wireless receiver with a direct conversion structure.

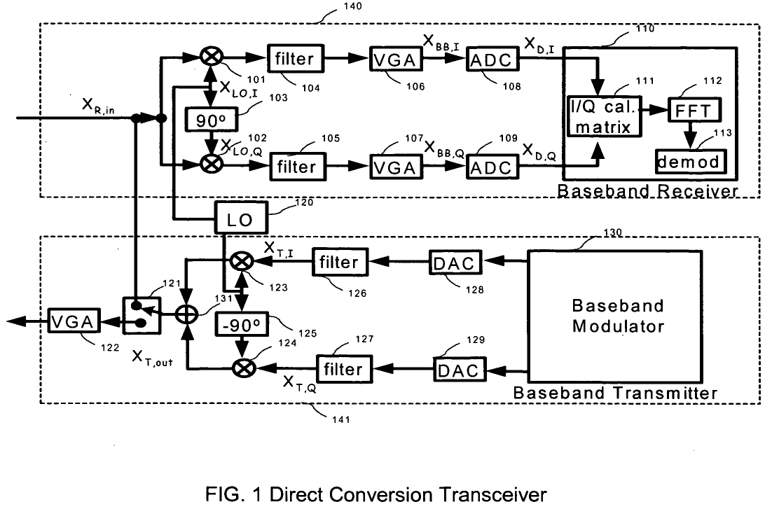

A direct conversion receiver 140 is illustrated in FIG. 1. The received radio signals X_{R,in} passing through a receiver antenna and a low noise amplifier (LNA) (not shown) are down-converted by an in-phase mixer 101 and a quadrature mixer 102. A local oscillator 120 generates sinusoidal waves for both the transmitter and receiver mixers. Phase-shifters 103 and 125 provide a 90-degree phase shift of sinusoidal waves to use in generating the quadrature signals. After mixing, the received signals are filtered by low pass filters (LPFs) 104 and 105 to remove high frequency signal components. Receiver variable gain control amplifiers (VGA) 106 and 107 are controlled by an automatic gain control (AGC) in the baseband to provide suitable signal strength for the baseband processor. Analog-to-digital converters 108 and 109 convert the analog signals output by VGAs 106 and 107 to digital signals for processing in a receiver baseband processor 110. Receiver baseband processor 110 demodulates the digital received signals to recover the transmitted signals. The receiver baseband processor 110 includes DC calibration unit (not shown), I/Q calibration unit 111, an AGC unit (not shown), a receiver adjacent channel rejection filter (not shown), a Fast Fourier transformation (FFT) unit 112 and other signal processing units.

A transmitter 141 is also shown in the FIG. 1. In a normal transmit mode, a baseband modulator 130 prepares a baseband signal for transmission. Digital to analog converters (DACs) 128 and 129 convert the baseband signal to an analog signal for input to LPFs 126 and 127 to eliminate high frequency components of the analog signals. Mixers 123 and 124 multiply the corresponding input base-band signals X_{T,I} and X_{T,Q} by X_{LO,I} and X_{LO,Q}, respectively, to up-convert the transmitted signals to the desired radio channel having a carrier or center frequency of ω_{c}/2π. A combiner 131 sums the of mixers 123 and 124 to generate an RF signal. The generated RF signal is then passed through a transmitter VGA 122 for wireless transmission by the transmitter antenna.

The system for I/Q calibration is now described with reference to FIG. 1. Transmitter base-band modulator 130 generates a complex sinusoidal wave for calibration. The sinusoidal wave passes through DACs 128 and 129, LPFs 126 and 127 and quadrature mixers 123 and 124. During receiver calibration, a switch 121 connects the output of transmitter combiner 131 to the input of receiver 140. A loop-back path from the transmitter 141 to the receiver 140 is thus formed that feeds the sinusoidal wave generated in the transmitter to the receiver. In all other modes, switch 121 connects the output of the transmitter combiner 131 to the input of the transmitter VGA 122.

During receiver calibration, the generated sinusoidal wave passes through receiver mixers 101 and 102, LPFs 104 and 105, VGAs 106 and 107 and ADCs 108 and 109. During the calibration mode, the IQ calibration matrix 111 is basically transparent to the received signal. The received complex sinusoidal signals, i.e., the complex samples x_{D,I}+j·x_{D,Q}, are fed into FFT unit 112 for I/Q imbalance estimation. The FFT 112 is required for demodulating OFDM signals during normal receiver operation. Therefore, no additional hardware modification is needed. During normal receiving mode, the I/Q calibration matrix 111 operates in accordance with the parameter values estimated during calibration.

A more detailed description on I/Q imbalance and its calibration is now provided. The complete description includes three parts: (1) generation of the calibration signal for receiver calibration, (2) estimation of the I/Q imbalance parameters, and (3) implementation of the digital circuitry for I/Q imbalance compensation.

First, generation of the calibration signal will be presented. A complex single tone is transmitted from the base-band during calibration. At the output of the BB transmitter 130, the I and Q channel signals are:
x_{T,I}=A cos ωᵢt
x_{T,Q}=A sin ωᵢt (1)

where A is the amplitude including the transmitter path gain and ωᵢ is the frequency of the transmitted signal from the base-band. For simplicity of discussion below, it is assumed that the transmitter is fully calibrated and that DAC's 128 and 129 just convert x_{T,I} and x_{T,Q} into analog waveforms. It is also assumed that LPFs 126 and 127 do not cause significant distortion to x_{T,I} and x_{T,Q} as these two signals are in-band. If we further assume unity gain mixers 123 and 124, then the mixer 123 takes the two inputs: x_{T,I} and cos ω_{c}t and generates the following output:
x_{T,I}·cos ω_{c}t, (2a)

and the mixer 124 takes the two inputs: x_{T,Q} and −sin ω_{c}t and generates the following output:
−x_{T,Q}·sin ω_{c}t. (2b)

After the combiner 131 which sums the above two signals together, the transmitted calibration signal at the output of the combiner 131 can be represented as follows:
x_{T,out}=x_{T,I}·cos ω_{c}t−x_{T,Q}·sin ω_{c}t (3)

where ω_{c} is the carrier frequency. During receiver calibration, switch 121 will be set to connect the output, x_{T,out}, of the transmitter to the input of the RF receiver, X_{R,in}. Therefore, the input to the RF receiver is:
x_{R,in}=x_{T,out}=x_{T,I}·cos ω_{c}t−x_{T,Q}·sin ω_{c}t (3a)

In a direct conversion receiver, LPFs 104 and 105, VGAs 106 and 107, ADCs 108 and 109 can also contribute to the amplitude imbalance between the I/Q channels. To simplify the description, it is assumed that the I/Q imbalance is caused by the imperfection in mixers 101 and 102, LO 120 and 90-degree phase shifter 103 in the receiver path. Under these assumptions, the following equations represent the inputs x_{LO,I} and x_{LO,Q} to mixers 101 and 102:

$${x}_{LO , I} = 2 \cdot ( 1 + \frac{ɛ}{2} ) \cdot cos ( {ω}_{c} t + ϕ + \frac{θ}{2} ) \\ {x}_{LO , Q} = - 2 \cdot ( 1 - \frac{ɛ}{2} ) \cdot sin ( {ω}_{c} t + ϕ - \frac{θ}{2} ) \qquad ( 4 )$$

where ε is the gain imbalance, and θ is the phase imbalance two receiver mixers 101 and 102, and φ is the average phase of LO signals X_{LO,I} and X_{LO,Q}. An arbitrary gain factor of 2 in Eq. (4) is used to simplify the results. The RF received signal x_{R.in} is split before passing through the mixers 101 and 102 and filtering by the low-pass filters 104 and 105. Assuming (1) low-pass filters 104 and 105 remove the unwanted signals at 2ω_{c} and its filtering effect on the desired signal is negligible, and (2) the total gain of the receive filter and VGA is unity, the baseband signals at the input of ADC 108 and 109, respectively, are:

$${x}_{BB , I} = {x}_{T , I} \cdot ( 1 + \frac{ɛ}{2} ) \cdot cos ( ϕ + \frac{θ}{2} ) + {x}_{T , Q} \cdot ( 1 + \frac{ɛ}{2} ) \cdot sin ( ϕ + \frac{θ}{2} ) \\ {x}_{BB , Q} = - {x}_{T , I} \cdot ( 1 - \frac{ɛ}{2} ) \cdot sin ( ϕ - \frac{θ}{2} ) + {x}_{T , Q} \cdot ( 1 - \frac{ɛ}{2} ) \cdot cos ( ϕ - \frac{θ}{2} ) \qquad ( 5 )$$

where x_{BB,I} and x_{BB,Q} represent the in-phase and quadrature baseband signals, respectively. The corresponding complex representation of the base-band signal is:
x_{BB}=x_{BB,I}+j·x_{BB,Q}, (6)

where j=\sqrt{−1}. Substituting Eq. (1) into Eq. (5), using a complex representation of the baseband signal as in Eq. (6), and assuming θ is small yields the following complex representation of the baseband signal:

$${x}_{BB} = A cos ϕ \cdot cos \frac{θ}{2} \cdot ( {ⅇ}^{j {ϖ}_{i} t} + \frac{ɛ}{2} \cdot {ⅇ}^{- j {ϖ}_{i} t} ) - A sin ϕ \cdot sin \frac{θ}{2} \cdot ( {ⅇ}^{- j {ϖ}_{i} t} + \frac{ɛ}{2} \cdot {ⅇ}^{j {ϖ}_{i} t} ) - j \cdot A sin ϕ \cdot cos \frac{θ}{2} \cdot ( {ⅇ}^{j {ϖ}_{i} t} - \frac{ɛ}{2} \cdot {ⅇ}^{- {jϖ}_{i} t} ) + j \cdot A cos ϕ \cdot sin \frac{θ}{2} \cdot ( {ⅇ}^{- {jϖ}_{i} t} - \frac{ɛ}{2} \cdot {ⅇ}^{{jϖ}_{i} t} ) = A \cdot ( cos \frac{θ}{2} - j \cdot \frac{ɛ}{2} \cdot sin \frac{θ}{2} ) \cdot {ⅇ}^{j ( {ϖ}_{i} t - ϕ )} + A \cdot ( \frac{ɛ}{2} \cdot cos \frac{θ}{2} + j \cdot sin \frac{θ}{2} ) \cdot {ⅇ}^{- j ( {ϖ}_{i} t - ϕ )} \approx A \cdot ( 1 - j \cdot \frac{ɛ}{2} \cdot \frac{θ}{2} ) \cdot {ⅇ}^{j ( {ϖ}_{i} t - ϕ )} + A \cdot ( \frac{ɛ}{2} + j \cdot \frac{θ}{2} ) \cdot {ⅇ}^{- j ( {ϖ}_{i} t - ϕ )} \qquad ( 7 )$$

Because ε and θ are both small, the terms due to

$$\frac{ɛ}{2} \cdot \frac{θ}{2}$$

can be neglected, resulting in the following expression:

$${x}_{BB} \approx A \cdot {ⅇ}^{j ( {ϖ}_{i} t - ϕ )} + A \cdot ( \frac{ɛ}{2} + j \cdot \frac{θ}{2} ) \cdot {ⅇ}^{- j ( {ϖ}_{i} t - ϕ )} \qquad ( 8 )$$

In Eq. (8), x_{BB,I}+j·x_{BB,Q} vector represents the complex base-band received signal including the distortion due to I/Q imbalance. One can observe the following based on Eq. (8):

(a) In the absence of I/Q mismatch, that is, when ε and θ are both zero, x_{BB,I}+j·x_{BB,Q} is just a “phase rotated” version of the un-distorted receiver complex received signal:
x_{R,I}+j·x_{R,Q}.

(b) An image tone at −ωᵢ is present due to I/Q mismatch, with a complex magnitude proportional to the mismatch:

$$\frac{ɛ}{2} + j \cdot \frac{θ}{2} .$$

(c) A receiver calibration scheme needs to estimate φ, ε, and θ before a proper calibration circuitry can be used to correct the I/Q mismatch.

(d) In Eq. (8), φ is equivalent to a time delay in sampling so it is unnecessary to compensate for φ. However, an estimate of φ is required to correctly estimate ε, and θ.

Since the calibration can be considered successful if the “delayed” signal e^{j(ω}^{ᵢ}^{t-φ)} in Eq. (8) can be recovered, the I/Q mismatch compensation can be achieved using the following matrix operation on the received signals:

$$( \begin{matrix}{x}_{R , I} \\ {X}_{R , Q}\end{matrix} ) = \frac{1}{cos θ} \cdot ( \begin{matrix}cos \frac{θ}{2} & - sin \frac{θ}{2} \\ - sin \frac{θ}{2} & cos \frac{θ}{2}\end{matrix} ) \cdot ( \begin{matrix}\frac{1}{1 + \frac{ɛ}{2}} & 0 \\ 0 & \frac{1}{1 - \frac{ɛ}{2}}\end{matrix} ) \cdot ( \begin{matrix}{x}_{BB , I} \\ {x}_{BB , Q}\end{matrix} ) \qquad ( 9 )$$

The above I/Q imbalance compensation matrix is frequency independent. This implies the I/Q imbalance compensation can be applied to any modulated signal. The presence of an I/Q mismatch causes receiver signals, X_{R,in}, to be distorted to X_{BB,I}+jX_{BB,Q} during normal receiver mode. The distortion can be corrected by applying an equivalent matrix operation on

$$( \begin{matrix}{x}_{BB , I} \\ {x}_{BB , Q}\end{matrix} ) .$$

A couple of implementation examples based on Eq. (9) are provided below.

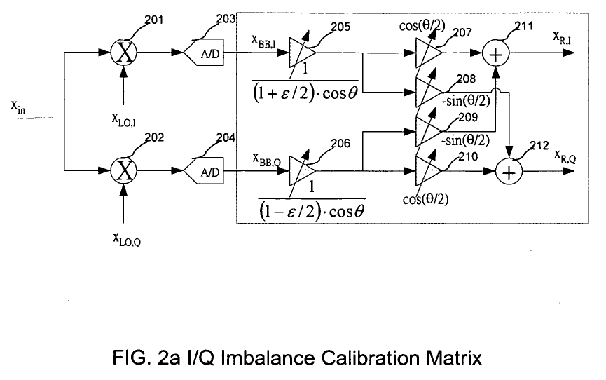

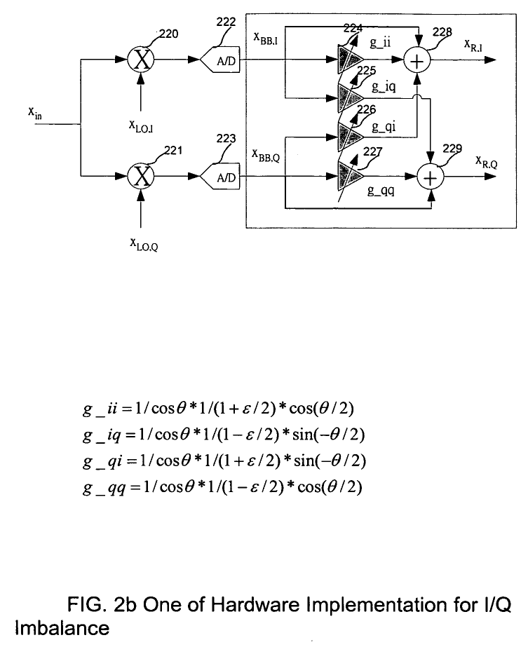

Assuming ε, and θ have been estimated, FIGS. 2a and 2b provide I/Q imbalance compensation circuitry according to embodiments of the present invention. With the estimated amplitude and phase imbalance, the compensation factors are inserted in each amplifier (205, 206, 207, 208, 209 and 210) to mitigate the impact of the I/Q mismatch on the receiver signals. Adders 211 and 212 sum the amplified signals from both the in-phase and quadrature signals. After I/Q imbalance compensation, received signals, X_{R,I} and X_{R,Q}, are ready for further signal processing in the baseband receiver.

FIG. 2b illustrates a hardware implementation for compensating for I/Q imbalance according to another embodiment of the present invention. The embodiment illustrated in FIG. 2b is derived from the embodiment illustrated in FIG. 2a by combining (1) blocks 205 and 207 into one block 224, (2) blocks 205 and 208 into one block 225, (3) blocks 206 and 209 into one block 226, (4) blocks 206 and 210 into one block 227, and (5) X_{BB,I} and X_{BB,Q} are added by blocks 228 and 229. With these modifications, only four factors are present in the calibration matrix and it is easier to implement. Because θ, typically, is very close to zero, in most applications there is no need to include the “1/cos θ” in the calibration circuit, as it is approximately 1.

What remains to be discussed is the estimation of φ, ε, and θ based on Eq. (8). An algorithm showing the I/Q imbalance calibration procedure is presented below:

Step 1: Transmitter 141 is configured to generate a complex sinusoidal wave with a center frequency at ωᵢ (in radian/sec). Switch 121 is configured to connect the output of transmitter combiner 131 to the receiver input so the generated sinusoidal signal goes directly into the receiver as described in the above paragraphs. The received signal is split, and passes through the in-phase and the quadrature mixers 101 and 102, LPFs 104 and 105, VGAs 106 and 107, and ADCs 108 and 109. An FFT is performed on the digitized samples (X_{D,I}, X_{D,Q}) by treating these samples as complex numbers X_{D,I}+j X_{D,Q}. Assume (Xᵢ, X₋ᵢ) are the complex-valued FFT output values corresponding to (ωᵢ, −ωᵢ).

Step 2: Find φ=tan⁻¹(Im(Xi)/Re(Xi)), where Re( ) function gives the real part of a given complex number, and the Im( ) function gives the imaginary part of the complex number.

Step 3: Rotate X₋ᵢ by φ, Rotate Xᵢ by −φ, where φ is the phase of Xᵢ calculated in Step 2. Step 4: An estimate of the receiver magnitude imbalance is calculated as ε=2 Re(X₋ᵢ)/Re(Xᵢ), and an estimate of the receiver phase imbalance is calculated as θ=2 Im(X₋ᵢ)/Re(Xᵢ).

All the above computations required for the estimation of I/Q mismatch, other than the sinusoidal signal generation and the FFT, can be implemented in software driver to minimize the hardware cost.

Although 802.11g and 802.11a receivers are candidates for direct applications of the receiver calibration scheme proposed herein, it will be recognized by those skilled in the art embodiments of the present invention can be used in any communication receivers in which I/Q mismatch calibration can enhance the receiver performance. Those skilled in the art will appreciate that the embodiments described above are non-limiting examples only, and that certain modifications can be made without departing from the spirit and scope thereof. The accompanying claims are intended to cover such modifications as would fall within the true scope and spirit of the present invention.

What is claimed is:

1. An apparatus, comprising:
a modulator to generate a complex sinusoidal signal;
a receiver to receive the generated complex sinusoidal signal;
a processor to estimate an I/Q imbalance using the received complex sinusoidal signal and to calibrate the I/Q imbalance to determine I/Q calibration factors to apply to subsequently received signals.

2. The apparatus as recited in claim 1, comprising a transmitter to generate the complex sinusoidal signal.

3. The apparatus as recited in claim 1, wherein the receiver comprises a local oscillator and a 90-degree phase shifter, and wherein the I/Q imbalance is caused by the local oscillator and by the 90-degree phase shifter.

4. The apparatus as recited in claim 1, further comprising a switch to choose between a calibration mode and a normal receiving/transmitting mode.

5. The apparatus as recited in claim 4, wherein the processor uses the generated complex sinusoidal signal to estimate the I/Q imbalance in a calibration mode of operation.

6. The apparatus as recited in claim 4, wherein the estimated I/Q imbalance is used to calibrate the input signal in the normal receiving/transmitting mode.

7. The apparatus as recited in claim 1, wherein the processor estimates the I/Q imbalance by estimating a phase φ, a gain imbalance ε, and a phase imbalance θ using the complex sinusoidal signal.

8. The apparatus as recited in claim 7, wherein the processor calibrates the input signal using the estimated phase φ, gain imbalance ε, and phase imbalance θ.

9. The apparatus as recited in claim 8, wherein the processor transforms input signals according to the following equation:
$$( \begin{matrix}{x}_{R , I} \\ {X}_{R , Q}\end{matrix} ) = \frac{1}{cos θ} \cdot ( \begin{matrix}cos \frac{θ}{2} & - sin \frac{θ}{2} \\ - sin \frac{θ}{2} & cos \frac{θ}{2}\end{matrix} ) \cdot ( \begin{matrix}\frac{1}{1 + \frac{ɛ}{2}} & 0 \\ 0 & \frac{1}{1 - \frac{ɛ}{2}}\end{matrix} ) \cdot ( \begin{matrix}{x}_{BB , I} \\ {x}_{BB , Q}\end{matrix} )$$
wherein X_{BB,I} and X_{BB,Q} are input I/Q signals, and X_{R,I} and X_{R,Q} are output I/Q signals.

10. The apparatus as recited in claim 1, wherein the processor is implemented in hardware.

11. The apparatus as recited in claim 1, wherein the processor is implemented in software.

12. A method for calibrating I/Q imbalance, comprising:
generating a complex sinusoidal signal;
estimating an I/Q imbalance using the generated complex sinusoidal signal; and
calibrating the input signal according to the estimated I/Q imbalance.

13. The method for calibrating I/Q imbalance as recited in claim 12, further comprising: sending the complex sinusoidal signal to a receiver to obtain in-phase and quadrature input signals X_{BB,I}, X_{BB,Q};
estimating a phase φ of the received input signals; and
estimating a gain imbalance ε and a phase imbalance θ.

14. The method for calibrating I/Q imbalance as recited in claim 13, wherein the generated complex sinusoidal signal has a center frequency of ω_{I}, and wherein the I/Q imbalance produces an image tone at −ωᵢ with a complex magnitude proportional to the I/Q gain imbalance ε and phase imbalance θ:
$$\frac{ɛ}{2} + j \cdot \frac{θ}{2} .$$

15. The method for calibrating I/Q imbalance as recited in claim 14, further comprising: obtaining digitized input signal samples (X_{D,I}, X_{D,Q}) from I/Q input signals (X_{BB,I}, X_{BB,Q}); performing an FFT operation on the digitized samples (X_{D,I}, X_{D,Q}) by treating the digitized samples as complex numbers (X_{D,I}+j X_{D,Q}), thereby generating complex-valued FFT output values (Xᵢ, X₋ᵢ) corresponding to −(ωᵢ, −ωᵢ);
computing φ=tan⁻¹(Im(Xi)/Re(Xi));
rotating X₋ᵢ by φ;
rotating Xᵢ by −φ; computing a receiver magnitude imbalance ε=2 Re(X₋ᵢ)/Re(Xᵢ); and
computing a receiver phase imbalance θ=2 Im(X₋ᵢ)/Re(Xᵢ).

16. The method for calibrating imbalance as recited in claim 15, comprising: generating output I/Q signals X_{R,I}, X_{R,Q} from input I/Q signals X_{BB,I}, X_{BB,Q} signals according to the following equation,
$$( \begin{matrix}{x}_{R , I} \\ {x}_{R , Q}\end{matrix} ) = \frac{1}{cos θ} \cdot ( \begin{matrix}cos \frac{θ}{2} & - sin \frac{θ}{2} \\ - sin \frac{θ}{2} & cos \frac{θ}{2}\end{matrix} ) \cdot ( \begin{matrix}\frac{1}{1 + \frac{ɛ}{2}} & 0 \\ 0 & \frac{1}{1 - \frac{ɛ}{2}}\end{matrix} ) \cdot ( \begin{matrix}{x}_{BB , I} \\ {x}_{BB , Q}\end{matrix} )$$

17. A method for correcting for I/Q imbalance, comprising:
generating a calibration signal in a calibration mode;
determining one or more calibration factors to correct for I/Q imbalance using the generated calibration signal in the calibration mode; and
applying the calibration factors to a received signal in a normal receive mode to compensate the I/Q imbalance.

18. The method as recited in claim 17, further comprising:
using a transmitter portion of a receiver-transmitter to generate the calibration signal; and
applying the calibration signal to a receiver portion of the receiver transmitter.

19. The method as recited in claim 17, further comprising determining an I/Q imbalance calibration matrix for use in correcting for I/Q imbalance.

20. The method as recited in claim 17, wherein the complex sinusoidal has a center frequency of ω_{I}, further comprising:
calculating I/Q input signals (X_{BB,I}, X_{BB,Q});
deriving digitized input signal samples (X_{D,I}, X_{D,Q}) from I/Q input signals X_{BB,I}, X_{BB,Q};
performing FFT on the digitized samples (X_{D,I}, X_{D,Q}) by treating these samples as complex numbers X_{D,I}+jX_{D,Q} to generate complex-valued FFT output values
(Xᵢ, X₋ᵢ) corresponding to (ωᵢ, −ωᵢ);
computing φ=tan⁻¹(Im(Xi)/Re(Xi)), where Re( ) function gives the real part of a given complex number, and the Im( ) function gives the imaginary part of the complex number;
rotating X₋ᵢ by φ;
rotating Xᵢ by −φ; and computing a receiver magnitude imbalance ε and a receiver phase imbalance θ.
